(19) United States
(12) Patent Application Publication
(10) Pub. No.: US 2014/0209997 A1
(43) Pub. Date: Jul. 31, 2014

(54) THIN FILM TRANSISTOR

(71) Applicants: HON HAI PRECISION INDUSTRY CO., LTD., New Taipei (TW); Tsinghua University, Beijing (CN)

(72) Inventors: QING-KAI QIAN, Beijing (CN); QUN-QING LI, Beijing (CN)

(21) Appl. No.: 13/928,365

(22) Filed: Jun. 26, 2013

(30) Foreign Application Priority Data
Jan. 31, 2013 (CN) 2013100370080

(51) Int. Cl. H01L 29/786

(52) U.S. Cl. CPC H01L 29/78696; Y10S 977/742; Y10S 977/938; B82Y 10/00
USPC 257/327; 977/742; 977/938

(57) ABSTRACT

A thin film transistor based on carbon nanotubes includes a source electrode, a drain electrode, a semiconducting layer, an insulating layer and a gate electrode. The drain electrode is spaced apart from the source electrode. The semiconductor layer is electrically connected with the source electrode and the drain electrode. The gate electrode is insulated from the source electrode, the drain electrode, and the semiconductor layer by the insulating layer. The work-functions of the source electrode and of the drain electrode are different from that of the semiconductor layer, enabling the creation of both p-type and n-type field-effect transistors.

This application claims all benefits accruing under 35 U.S.C. §119 from China Patent Application No. 201310037008.0, filed on Jan. 31, 2013 in the China Intellectual Property Office.

### BACKGROUND

1. Technical Field

The present invention relates to thin film transistors and, particularly, to a carbon nanotube based thin film transistor.

2. Description of Related Art

A typical thin film transistor (TFT) is made of a substrate, a gate electrode, an insulation layer, a drain electrode, a source electrode, and a semiconducting layer. The thin film transistor performs a switching operation by modulating an amount of carriers accumulated in an interface between the insulation layer and the semiconductor layer from an accumulated state to a depletion state, with applied voltage to the gate electrode, to change an amount of the current passing between the drain electrode and the source electrode.

In order to prepare an N-type or P-type carbon nanotube field-effect transistor, two electrodes with predetermined work-function material such as palladium, or scandium, can be used to fabricate the source electrode and the drain electrode. The mechanism is to selectively generate holes or electrons, thereby allowing the TFT to exhibit unipolar characteristic. However, the source electrode and the drain electrode with predetermined work-function material cannot exhibit totally unipolar characteristics, due to the Fermi level pinning of the carbon nanotube.

What is needed, therefore, is a TFT that can overcome the above-described shortcomings.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a cross sectional view of one embodiment of a thin film transistor.

FIG. 2 is a schematic view of the thin film transistor of FIG. 1 connected to a circuit.

FIG. 3 is a cross sectional view of another embodiment of a thin film transistor.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

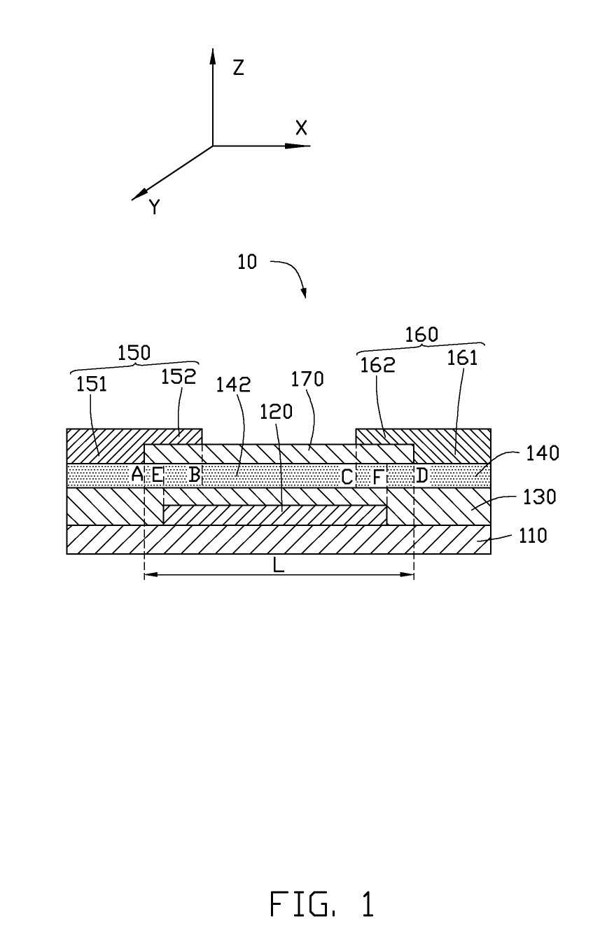

Referring to FIG. 1, a thin film transistor 10 of one embodiment includes a gate electrode 120, a first insulating layer 130, a semiconductor layer 140, a source electrode 150, a drain electrode 160, and a second insulating layer 170. The thin film transistor 10 is located on a surface of the insulating substrate 110. The source electrode 150 and the drain electrode 160 are spaced from each other and electrically connected to the semiconductor layer 140. The gate electrode 120 is insulated from the semiconductor layer 140, the source electrode 150, and the drain electrode 160 because of the first insulating layer 130.

The insulating substrate 110 supports the thin film transistor 10. The material of the insulating substrate 110 can be the same as a substrate of a printed circuit board (PCB), and can be rigid materials (e.g., p-type or n-type silicon, silicon with an silicon dioxide layer formed thereon, crystal, crystal with a oxide layer formed thereon), or flexible materials (e.g., plastic or resin). In one embodiment, the material of the insulating substrate is glass. The shape and size of the insulating substrate 110 is arbitrary. The plurality of thin film transistors 10 can be located on the insulating substrate 110 in a predetermined order.

The thin film transistor 10 can be a bottom gate structure. The gate electrode 120 is located on the insulating substrate 110, and the first insulating layer 130 covers the gate electrode 120. The semiconductor layer 140 is located on the first insulating layer 130, and insulated from the gate electrode 120 through the first insulating layer 130. The source electrode 150 and the drain electrode 160 are spaced apart from each other and electrically connected to the semiconductor layer 140. A channel 142 is formed in the semiconductor layer 140 at a region between the source electrode 150 and drain electrode 160. The channel 142 is a portion of the semiconductor layer 140.

The second insulating layer 170 is located on the semiconductor layer 140. The source electrode 150 is insulated from the drain electrode 160 by the second insulating layer 170. The source electrode 150 defines a first body 151 and a first extending portion 152 connected to the first body 151. The first body 151 is directly located on the semiconductor layer 140. The first extending portion 152 is located on a surface of the second insulating layer 170, away from the semiconductor layer 140, and extends toward the drain electrode 160. In one embodiment, the first extending portion 152 is integrated with the first body 151 to form an integrated structure.

The drain electrode 160 defines a second body 161 and a second extending portion 162, connected to the second body 161. The second body 161 is directly located on the semiconductor layer 140. The second extending portion 162 is located on the surface of the second insulating layer 170, away from the semiconductor layer 140. The second extending portion 162 is opposite to the first extending portion 152 and extends toward the first extending portion 152. Thus the channel 142 is the region of the semiconductor layer 140 between the first body 151 and the second body 161. In one embodiment, the second extending portion 162 is integrated with the second body 161 to form an integrated structure.

The material of the first body 151 can be different from the first extending portion 152. The material of the second body 161 can also be different from the second extending portion 162.

An extending direction of the first extending portion 152 is defined as a first direction X, based on Cartesian coordinates. A second direction Y is perpendicular to the first direction X and parallel to the surface of the insulating substrate 110. A third direction Z is perpendicular with the first direction X and the second direction Y. The first extending portion 152 and the second extending portion 162 cover a part of the channel 142. The term “cover” means that, an orthographic projection of the first extending portion 152 along Z direction, an orthographic projection of the second extending portion 162 along Z direction, and an orthographic projection of gate electrode 120 along Z direction gives a partial overlap. In detail, a length of the first extending portion 152 along the first direction is defined as AB, and a length of the second extending portion 162 along the first direction is defined as CD. A length of the gate electrode 120 along the first direction is defined as EF. A length of the channel 142 along the first direction is defined as L. In one embodiment, AB, CD, EF, and L satisfy following formula: AB+CD+EF≧L.

The work-function of the first extending portion 152 is same as that of the second extending portion 162, and different from the work-function of the semiconductor layer 140. In one embodiment, a first part of the semiconductor layer 140 under the first extending portion 152 will be modulated by the first extending portion 152. The length of the first part is equal to the length of the first extending portion 152. A second part of the semiconductor layer 140 under the second extending portion 162 will be modulated by the second extending portion 162. A plurality of carriers will be induced on the second part of the semiconductor layer 140, and the type of the plurality of carriers depends on the work-function of the first extending portion 152 and the work-function of the semiconductor layer 140. In one embodiment, the work-function of the first extending portion 152 and the second extending portion 162 is higher than the work-function of the semiconductor layer 140. The electrons in the semiconductor layer 140, under the first extending portion 152, will flow towards the first extending portion 152, and the electrons in the semiconductor layer 140, under the second extending portion 162, will flow towards the second extending portion 162. Thus the type of the plurality of carriers will be hole, and the TFT 10 will exhibit P-type unipolar characteristics. In another embodiment, the work-function of the first extending portion 152 and the second extending portion 162 is lower than the work-function of the semiconductor layer 140, thus the type of the plurality of charge-carriers will be electrons, and the TFT 10 will exhibit N-type unipolar characteristics. By selecting different materials of the first extending portion 152 and the second extending portion 162, the type of the TFT 10 can be selected.

The semiconductor layer 140 includes a plurality of carbon nanotube wires. A part of the plurality of carbon nanotube wires includes a first end and a second end opposite to the first end. The first end is electrically connected to the source electrode 150, and the second end is electrically connected to the drain electrode 160. The plurality of carbon nanotube wires intersects with each other to form a conductive network, and the plurality of carbon nanotube wires can also be parallel with each other. In one embodiment, the plurality of carbon nanotube wires is parallel with each other and extends along a direction from the source electrode 150 to the drain electrode 160. The plurality of carbon nanotube wires is spaced from each other. A distance between adjacent two adjacent carbon nanotube wires ranges from about 0 millimeters to about 1 millimeters. The first end of the plurality of carbon nanotube wires is electrically connected to the source electrode 150, and the second end of the plurality of carbon nanotube wires is electrically connected to the drain electrode 160.

The carbon nanotube wire can be twisted carbon nanotube wire or untwisted carbon nanotube wire. In one embodiment, the carbon nanotube wire can be untwisted. The carbon nanotube wire includes a plurality of carbon nanotubes aligned along an axial direction of the carbon nanotube wire. The untwisted carbon nanotube wire includes a plurality of carbon nanotubes substantially oriented along a same direction (i.e., a direction of the length of the untwisted carbon nanotube wire). The carbon nanotubes are parallel to the axis of the untwisted carbon nanotube wire. The untwisted carbon nanotube wire can be drawn from a super-aligned carbon nanotube array. More specifically, the untwisted carbon nanotube wire includes a plurality of successive carbon nanotube segments joined end to end by van der Waals attractive force therebetween. Each carbon nanotube segment includes a plurality of carbon nanotubes substantially parallel to each other, and combined by van der Waals attractive force therebetween. The carbon nanotube segments can vary in width, thickness, uniformity and shape. Length of the untwisted carbon nanotube wire can be arbitrarily set as desired. A diameter of the untwisted carbon nanotube wire ranges from about 0.5 nm to about 100 μm. The twisted carbon nanotube wire can be formed by twisting a drawn carbon nanotube film using a mechanical force to turn the two ends of the drawn carbon nanotube film in opposite directions. The twisted carbon nanotube wire includes a plurality of carbon nanotubes helically oriented around the axial direction of the twisted carbon nanotube wire. More specifically, the twisted carbon nanotube wire includes a plurality of successive carbon nanotube segments joined end to end by van der Waals attractive force therebetween. Each carbon nanotube segment includes a plurality of carbon nanotubes parallel to each other, and combined by van der Waals attractive force therebetween. Length of the carbon nanotube wire can be set as desired. A diameter of the twisted carbon nanotube wire can be from about 0.5 nm to about 100 μm. Further, the twisted carbon nanotube wire can be treated with a volatile organic solvent after being twisted. After being soaked by the organic solvent, the adjacent paralleled carbon nanotubes in the twisted carbon nanotube wire will bundle together, due to the surface tension of the organic solvent when the organic solvent evaporates. The specific surface area of the twisted carbon nanotube wire will decrease, while the density and strength of the twisted carbon nanotube wire will be increased.

The semiconductor layer 140 can also be a carbon nanotube film. The carbon nanotube film can be an ordered film or a disordered film. In the disordered film, the carbon nanotubes are disordered. The disordered carbon nanotubes are entangled with each other to form the disordered carbon nanotube film, and a plurality of apertures is defined by the carbon nanotubes. A diameter of the aperture can smaller than 50 micrometers. The plurality of the apertures enhances the transparence of the carbon film. The disordered carbon nanotube film can be isotropic. In the ordered film, the carbon nanotubes are primarily oriented along the same direction and perpendicular to a surface of the first insulating layer 130. The carbon nanotube film can be a super-aligned carbon nanotube array. The carbon nanotubes in the semiconductor layer 140 are semiconducting carbon nanotubes. The carbon nanotubes can be single-walled carbon nanotubes, double-walled carbon nanotubes, or combination thereof. A diameter of the single-walled carbon nanotubes is in the range from about 0.5 nanometers to about 50 nanometers.

The source electrode 150, the drain electrode 160, and/or the gate electrode 120 are made of conductive material. In the present embodiment, the source electrode 150, the drain electrode 160, and the gate electrode 120 are conductive films. A thickness of the conductive film can be in a range from about 0.5 nanometers to about 100 micrometers. The material of the source electrode 151, the drain electrode 160, and the gate electrode 120 can be selected from the group consisting of metal, metal alloy, indium tin oxide (ITO), antimony tin oxide (ATO), silver paste, conductive polymer, or metallic carbon nanotubes. The metal or metal alloy can be aluminum (Al), copper (Cu), tungsten (W), molybdenum (Mo), gold (Au), titanium (Ti), neodymium (Nd), palladium (Pd), cesium (Cs), scandium (Sc), hafnium (Hf), potassium (K), sodium (Na), lithium (Li), nickel (Ni), rhodium (Rh), or platinum (Pt), and combinations of the above-mentioned metals. The work-functions of aluminum (Al), titanium (Ti), scandium (Sc), hafnium (Hf), potassium (K), sodium (Na), and lithium (Li) are lower than that of the carbon nanotubes. Thus the type of TFT 10 will be N-type. The work-functions of nickel (Ni), rhodium (Rh), palladium (Pd), and platinum (Pt) are higher than that of the carbon nanotubes. Thus the type of TFT 10 will be P-type.

In one embodiment, the source electrode 150, the drain electrode 160, and the gate electrode 120 are Pd films. A thickness of the Pd film is about 40 nanometers.

The type of TFT 10 is P-type.

The material of the first insulating layer 130 and the second insulating layer 170 can be a rigid material such as aluminum oxide (Al₂O₃), silicon nitride (Si₃N₄), silicon dioxide (SiO₂), or a flexible material such as polyethylene terephthalate (PET), benzocyclobutenes (BCB), polyester or acrylic resins. A thickness of the first insulating layer 130 can be in a range from about 10 nanometers to about 100 micrometers. A thickness of the second insulating layer 170 can be in a range from about 10 nanometers to about 100 micrometers. In one embodiment, the material of the first insulating layer 130 and of the second insulating layer 170 is Al₂O₃.

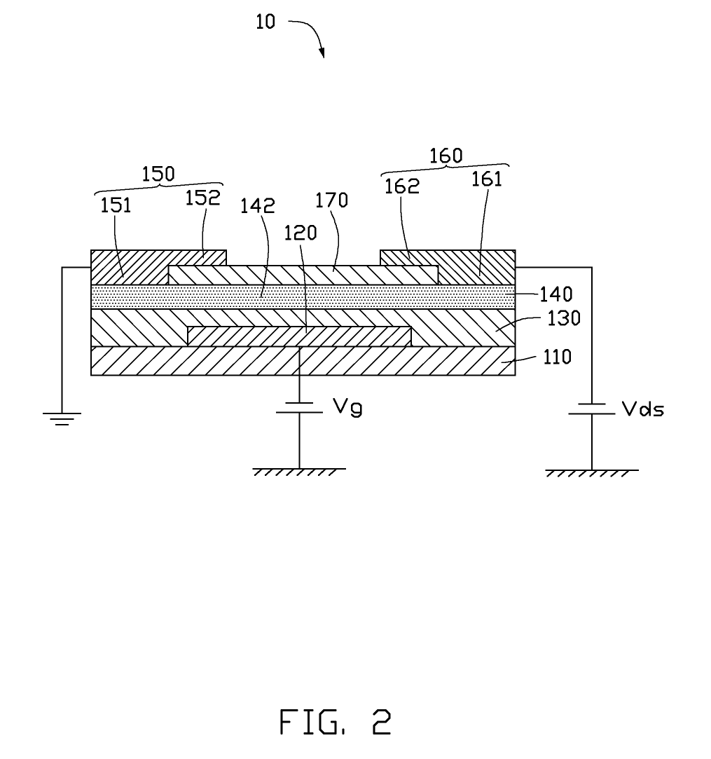

Referring to FIG. 2, in use, the source electrode 151 is grounded. A voltage Vds is applied to the drain electrode 160. Another voltage Vg is applied on the gate electrode 120. The voltage Vg forms an electric field in the channel 142 of the semiconducting layer 140. Accordingly, carriers will exist in the channel near the gate electrode 120. As the Vg increases, a current is generated and flows through the channel 142. Thus, the source electrode 150 and the drain electrode 160 are electrically connected.

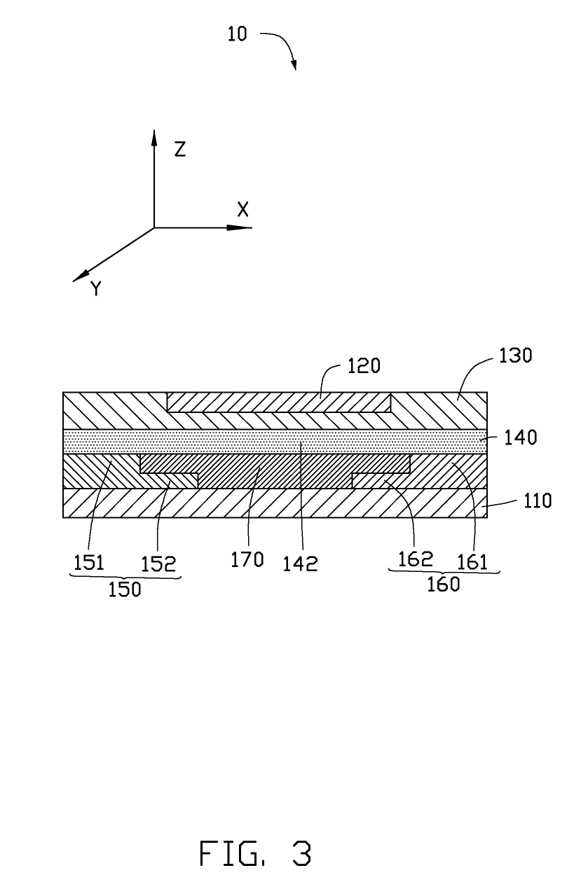

Referring to FIG. 3, a thin film transistor 20 with a bottom gate structure is provided. The thin film transistor 20 includes a gate electrode 120, a first insulating layer 130, a semiconductor layer 140, a source electrode 150, a drain electrode 160, and a second insulating layer 170. The thin film transistor 10 is located on a surface of the insulating substrate 110.

The structure of the thin film transistor 20 is similar to the structure of the thin film transistor 10, except that the thin film transistor 20 has a bottom gate structure. The source electrode 150 and the drain electrode 160 are located on the insulating substrate 110 and are spaced from each other, because of the second insulating layer 170. The semiconductor layer 140 covers the source electrode 150, the drain electrode 160, and the second insulating layer 170. The first insulating layer 130 is located on a surface of the semiconductor layer 140 away from the insulating substrate 11. The gate electrode 120 is located on the first insulating layer 130, and insulated from the semiconductor layer 140 because of the first insulating layer 130.

Depending on the embodiments, certain of the steps described may be removed, others may be added, and the sequence of steps may be altered. It is also to be understood that the description and the claims drawn to a method may include some indication in reference to certain steps. However, any indication used is only to be viewed for identification purposes and not as a suggestion as to an order for the steps.

It is to be understood, however, that even though numerous characteristics and advantages of the present embodiments have been set forth in the foregoing description, together with details of the structures and functions of the embodiments, the disclosure is illustrative only, and changes may be made in detail, especially in the matters of shape, size, and arrangement of parts within the principles of the disclosure.

What is claimed is:

1. A thin film transistor comprising:
a first insulating layer having a first surface and a second surface, opposite to the first surface;
a semiconductor layer on the first surface of the first insulating layer;
a gate electrode on the second surface of the first insulating layer; and
a source electrode on the semiconductor layer, wherein the source electrode comprises a first body and a first extending portion, the first body is attached on the surface of the semiconductor layer, and the first extending portion is insulated from the semiconductor layer;
a drain electrode on the semiconductor layer, wherein the drain electrode comprises a second body and a second extending portion, the second body is attached on the surface of the semiconductor layer, and the second extending portion is spaced from the semiconductor layer and the first extending portion, and a part of the semiconductor layer, between the first body and the second body, is defined as a channel, and the first extending portion and the second extending portion cover a part of the channel.

2. The thin film transistor of claim 1, wherein a length L of the channel satisfy following equation: AB+CD+EF≧L, wherein AB is a length of the first extending portion, CD is a length of the second extending portion, EF is a length of the gate electrode.

3. The thin film transistor of claim 2, wherein a first work-function of the first extending portion and a second work-function of the second extending portion are same.

4. The thin film transistor of claim 3, wherein the first work-function of the first extending portion and the second work-function of the second extending portion are different from a third work-function of the semiconductor layer.

5. The thin film transistor of claim 3, wherein the first extending portion comprises a material that is selected from the group consisting of aluminum, copper, tungsten, molybdenum, gold, titanium, neodymium, palladium, cesium, scandium, hafnium, potassium, sodium, lithium, nickel, rhodium, platinum, and combinations of the above-mentioned metal.

6. The thin film transistor of claim 1, wherein the semiconductor layer comprises a plurality of carbon nanotube wires electrically connected to the source electrode and the drain electrode.

7. The thin film transistor of claim 6, wherein the plurality of carbon nanotube wires intersects with each other to form a conductive network.

8. The thin film transistor of claim 6, wherein the plurality of carbon nanotube wires is parallel with each other and extends from the source electrode to the drain electrode.

9. The thin film transistor of claim 8, wherein a distance between adjacent two carbon nanotube wires ranges from about 0 millimeters to about 1 millimeter.

10. The thin film transistor of claim 6, wherein each of the plurality of carbon nanotube wires comprises a plurality of carbon nanotubes oriented along a same direction.

11. The thin film transistor of claim 10, wherein the plurality of carbon nanotubes extends along a direction from the source electrode to the drain electrode, and the plurality of carbon nanotubes are joined end to end by van der Waals attractive force therebetween.

12. The thin film transistor of claim 6, wherein each of the plurality of carbon nanotube wires comprise a plurality of carbon nanotubes helically oriented around an axial direction of the each of the plurality of carbon nanotube wires.

13. The thin film transistor of claim 1, wherein the semiconductor layer comprises a carbon nanotube film, and a plurality of apertures are defined in the carbon nanotube film.

14. The thin film transistor of claim 13, wherein the carbon nanotube film comprises a plurality of carbon nanotubes oriented along the same direction and perpendicular to the first surface of the first insulating layer.

15. The thin film transistor of claim 13, wherein the carbon nanotube film is isotropic.

16. The thin film transistor of claim 1, wherein the first extending portion and the second extending portion is spaced from the semiconductor layer through a second insulating layer.

17. The thin film transistor of claim 16, wherein the first portion and the second portion are located on a surface of the second insulating layer and is separated from the semiconductor layer.

18. The thin film transistor of claim 16, wherein the first body and the second body is insulated by the second insulating layer.

19. The thin film transistor of claim 1, wherein the first extending portion and the second extending portion extend toward to each other.

20. A thin film transistor comprising:
a source electrode;
a drain electrode spaced apart from the source electrode;
a semiconducting layer electrically connected to the source electrode and to the drain electrode;
an insulating layer on the semiconductor layer; and
a gate electrode insulated from the source electrode, the drain electrode, and the semiconducting layer by the insulating layer;
wherein a first work-function of the source electrode and a second work-function of the drain electrode is the same, and the first work function is different from a third work-function of the semiconducting layer.
